(19) United States
(12) Patent Application Publication
(10) Pub. No.: US 2024/0049510 A1
(43) Pub. Date: Feb. 8, 2024

(54) DISPLAY DEVICE

(71) Applicants: Samsung Display Co., LTD., Yongin-si (KR); Industry-University Cooperation Foundation Hanyang University ERICA Campus, Ansan-si (KR)

(72) Inventors: Joon Seok PARK, Yongin-si (KR); Saeroonter OH, Seoul (KR); Su Hyun KIM, Seongnam-si (KR); Taeho LEE, Hwaseong-si (KR); Hye Lim CHOI, Yongin-si (KR); Jun Hyung LIM, Yongin-si (KR)

(73) Assignees: Samsung Display Co., LTD., Yongin-si (KR); Industry-University Cooperation Foundation Hanyang University ERICA Campus, Ansan-si (KR)

(21) Appl. No.: 18/312,637

(22) Filed: May 5, 2023

(30) Foreign Application Priority Data
Aug. 3, 2022 (KR) 10-2022-0096802

(51) Int. Cl. H10K 59/121; H10K 59/124

(52) U.S. Cl. CPC H10K 59/1216; H10K 59/124

(57) ABSTRACT

According to an embodiment, a display device includes: a first capacitor electrode disposed on a substrate to include a first conductive layer and a second conductive layer disposed on the first conductive layer; a buffer layer disposed on the first capacitor electrode; a second capacitor electrode disposed on the buffer layer; a driving transistor disposed on the substrate; and a storage capacitor disposed on the substrate and electrically connected to the driving transistor, wherein the first capacitor electrode includes a concave portion and a convex portion depending on a pattern of the second conductive layer disposed on the first conductive layer, the buffer layer and the second capacitor electrode each include protrusions and depressions corresponding to the concave portion and the convex portion of the first capacitor electrode, and the first capacitor electrode and the second capacitor electrode form two electrodes of the storage capacitor.

### CROSS-REFERENCE TO RELATED APPLICATION(S)

This application claims priority to and benefits of Korean Patent Application No. 10-2022-0096802, under 35 U.S.C. § 119, filed on Aug. 3, 2022, in the Korean Intellectual Property Office, the entire contents of which are incorporated herein by reference.

### BACKGROUND

### 1. Technical Field

The disclosure relates to a display device and a manufacturing method thereof.

### 2. Description of the Related Art

A display device is a device that displays an image, and a liquid crystal display, an emissive display device, or the like is used.

The display device includes a pixel, and the pixel may include a light emitting diode such as an organic light emitting diode or an inorganic light emitting diode. A display device including a light emitting diode includes a driving transistor for controlling an amount of current flowing through the light emitting diode and a storage capacitor for maintaining a gate voltage of the driving transistor.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

As resolution of a display device increases, an area allocated to each pixel becomes narrow, and accordingly, an area for positioning a driving transistor or a storage capacitor may become narrow. It may be advantageous to increase the area of the capacitor within a given space in order to maintain a stable voltage and reduce generation of noise during external compensation.

Embodiments may provide a display device and a manufacturing method for increasing capacitance by increasing an electrode area of a capacitor in a given space.

Embodiments may provide a display device and a manufacturing method stably performing external compensation by increasing capacitance of a capacitor in a given space.

An embodiment provides a display device which may include a first capacitor electrode disposed on a substrate to include a first conductive layer and a second conductive layer disposed on the first conductive layer; a buffer layer disposed on the first capacitor electrode; a second capacitor electrode disposed on the buffer layer; a driving transistor disposed on the substrate; and a storage capacitor disposed on the substrate and electrically connected to the driving transistor, wherein
the first capacitor electrode may include a concave portion and a convex portion depending on a pattern of the second conductive layer, the buffer layer and the second capacitor electrode may each include protrusions and depressions corresponding to the concave portion and the convex portion of the first capacitor electrode, and the first capacitor electrode and the second capacitor electrode form two electrodes of the storage capacitor.

In an embodiment the driving transistor may include: a semiconductor disposed on the buffer layer to include a channel region, a first region, and a second region; a gate electrode that overlaps the channel region in a plan view; a first electrode electrically connected to the first region of the semiconductor; and a second electrode electrically connected to the second region of the semiconductor.

In an embodiment the second conductive layer may be thicker than the first conductive layer.

In an embodiment a thickness of the second conductive layer may be equal to or greater than about 5000 Å.

In an embodiment the first conductive layer may include titanium or a transparent conductive oxide.

In an embodiment the second conductive layer may include copper or aluminum.

In an embodiment the second capacitor electrode and the semiconductor of the driving transistor may be on a same layer.

In an embodiment the display device may further include a light blocking layer disposed on the substrate and spaced apart from the first capacitor electrode, wherein the light blocking layer may be connected to the first electrode of the driving transistor.

In an embodiment the display device may further include a wire disposed on the substrate and spaced apart from the light blocking layer and the first capacitor electrode, wherein the wire may be electrically connected to the second electrode of the driving transistor.

In an embodiment the first capacitor electrode, the light blocking layer, and the wire may be on a same layer.

An embodiment provides a display device which may include a first capacitor electrode disposed on a substrate to include a first conductive layer and a second conductive layer disposed on the first conductive layer; a buffer layer disposed on the first capacitor electrode; a third conductive layer disposed on the buffer layer, a driving transistor disposed on the substrate; and a storage capacitor disposed on the substrate and electrically connected to the driving transistor, wherein

the first capacitor electrode may include a concave portion and a convex portion depending on a pattern of the second conductive layer, the buffer layer and the third conductive layer each include protrusions and depressions corresponding to the concave portion and the convex portion of the first capacitor electrode, and the first capacitor electrode and the third conductive layer form the two electrodes of the storage capacitor.

In an embodiment the driving transistor may include: a semiconductor disposed on the buffer layer to include a channel region, a first region, and a second region; a gate electrode that overlaps the channel region in a plan view; a first electrode electrically connected to the first region of the semiconductor; and a second electrode electrically connected to the second region of the semiconductor.

In an embodiment the second conductive layer may be thicker than the first conductive layer.

In an embodiment the display device may further include a gate insulating layer disposed on the buffer layer, wherein the gate insulating layer may include protrusions and depressions corresponding to the concave portion and the convex portion of the first capacitor electrode.

In an embodiment the third conductive layer of the storage capacitor and the gate electrode of the driving transistor may be on a same layer.

An embodiment provides a display device which may include a first capacitor electrode disposed on a substrate to include a first conductive layer and a second conductive layer disposed on the first conductive layer; a buffer layer disposed on the first capacitor electrode; a second capacitor electrode disposed on the buffer layer; an interlayer insulating layer disposed on the second capacitor electrode; a fourth conductive layer disposed on the interlayer insulating layer; a driving transistor disposed on the substrate; and a first storage capacitor and a second storage capacitor disposed on the substrate and electrically connected to the driving transistor, wherein

the first capacitor electrode may include a concave portion and a convex portion depending on a pattern of the second conductive layer, the buffer layer, the second capacitor electrode, the interlayer insulating layer, and the fourth conductive layer may each include protrusions and depressions corresponding to the concave portion and the convex portion of the first capacitor electrode, the first capacitor electrode and the second capacitor electrode may form two electrodes of the first storage capacitor, and the second capacitor electrode and the fourth conductive layer may form two electrodes of the second storage capacitor.

In an embodiment the driving transistor may include a semiconductor disposed on the buffer layer to include a channel region, a first region, and a second region; a gate electrode that overlaps the channel region in a plan view; a first electrode electrically connected to the first region of the semiconductor; and a second electrode electrically connected to the second region of the semiconductor.

In an embodiment the second capacitor electrode and the semiconductor of the transistor may be on a same layer.

In an embodiment the fourth conductive layer of the second storage capacitor and the first electrode of the transistor may be on a same layer.

In an embodiment a thickness of the second conductive layer may be thicker than a thickness of the first conductive layer.

According to the embodiments, capacitance of a storage capacitor may be increased even when a pixel area is reduced depending on an increase in resolution of a display device. Accordingly, sufficient capacitor capacitance may be secured, so that stable external compensation may be performed.

It is to be understood that the embodiments above are described in a generic and explanatory sense only and not for the purpose of limitation, and the disclosure is not limited to the embodiments described above.

### BRIEF DESCRIPTION OF THE DRAWINGS

FIG. 1 illustrates a schematic diagram of an equivalent circuit of a pixel of a display device according to an embodiment;

FIG. 2 illustrates a schematic cross-sectional view of a display device according to an embodiment;

FIG. 3 to FIG. 15 illustrate schematic process cross-sectional views showing a manufacturing method of a display device according to the embodiment of FIG. 2;

FIG. 16 illustrates a schematic cross-sectional view of a display device according to an embodiment;

FIG. 17 to FIG. 21 illustrate schematic process diagrams showing a manufacturing method of the display device according to the embodiment of FIG. 16;

FIG. 22 illustrates a schematic cross-sectional view of a display device according to an embodiment; and

FIG. 23 illustrates a schematic cross-sectional view of a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

It will be understood that the terms “connected to” or “coupled to” may refer to a physical, electrical and/or fluid connection or coupling, with or without intervening elements.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

The terms “overlap”, or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Further, throughout the specification, the phrase “in a plan view” means when an object portion is viewed from above, and the phrase “in a cross-sectional view” means when a cross-section taken by vertically cutting an object portion is viewed from the side. A direction parallel to one surface of a substrate may be defined as a horizontal direction, and a thickness direction of the substrate may be defined as a vertical direction.

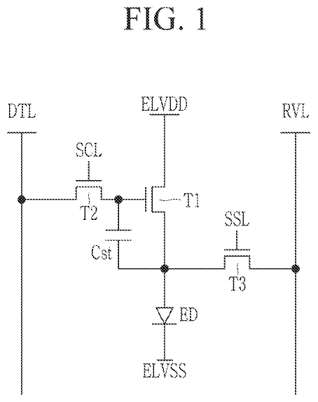

FIG. 1 illustrates a schematic diagram of an equivalent circuit diagram of a pixel of a display device according to an embodiment.

Referring to FIG. 1, each pixel of the display device according to an embodiment may include a light emitting diode ED, three transistors T1, T2, and T3, and a storage capacitor Cst. The light emitting diode ED emits light depending on a current supplied through the driving transistor T1. The light emitting diode ED may be implemented as an organic light emitting diode, a micro light emitting diode, or a nano light emitting diode.

A first electrode of the light emitting diode ED may be connected to a first source/drain electrode of the driving transistor T1, and a second electrode thereof may be connected to a second power line ELVSS to which a low potential voltage (second power voltage) that is lower than a high potential voltage (first power voltage) of a first power line ELVDD that is supplied.

The driving transistor T1 controls a current flowing from the first power line ELVDD to which the first power voltage may be supplied to the light emitting device ED depending on a voltage difference between a gate electrode and a source electrode. The gate electrode of the driving transistor T1 may be connected to a second source/drain electrode of the first switching transistor T2, the first source/drain electrodes of the driving transistor T1 may be connected to the first electrode of the light emitting diode ED, and the second source/drain electrode of the driving transistor T1 may be connected to the first power line ELVDD.

The first switching transistor T2 may be turned on by a scan signal of a scan line SCL to connect a data line DTL to the gate electrode of the driving transistor T1. A gate electrode of the first switching transistor T2 may be connected to the scan line SCL, the first source/drain electrodes of the first switching transistor T2 may be connected to the data line DTL, and the second source/drain electrode of the first switching transistor T2 may be connected to the gate electrode of the driving transistor T1.

The second switching transistor T3 may be turned on by a sensing signal of a sensing signal line SSL to connect a reference voltage line RVL to the first source/drain electrode of the driving transistor Ti. A gate electrode of the second switching transistor T3 may be connected to the sensing signal line SSL, a first source/drain electrode of the second switching transistor T3 may be connected to the reference voltage line RVL, and the second source/drain electrode of the second switching transistor T3 may be connected to the first source/drain electrode of the driving transistor T1.

In an embodiment, the first source/drain electrode of each of the driving transistor T1 and the first and second switching transistors T2 and T3 may be a source electrode, and the second source/drain electrode may be a drain electrode, but the disclosure is not limited thereto, and vice versa is also possible.

The storage capacitor Cst may be positioned between the gate electrode and the source electrode of the driving transistor T1. The storage capacitor Cst stores a difference voltage between the gate voltage and the source voltage of the driving transistor T1.

The driving transistor T1 and the first and second switching transistors T2 and T3 may each be formed of a thin film transistor. The driving transistor T1 and the first and second switching transistors T2 and T3 may be formed of an N-type metal oxide semiconductor field effect transistor (MOSFET), the driving transistor T1 and the first and second switching transistors T2 and T3 may be formed of a P-type MOSFET, some may be formed of an N-type MOSFET, or some may be formed of a P-type MOSFET.

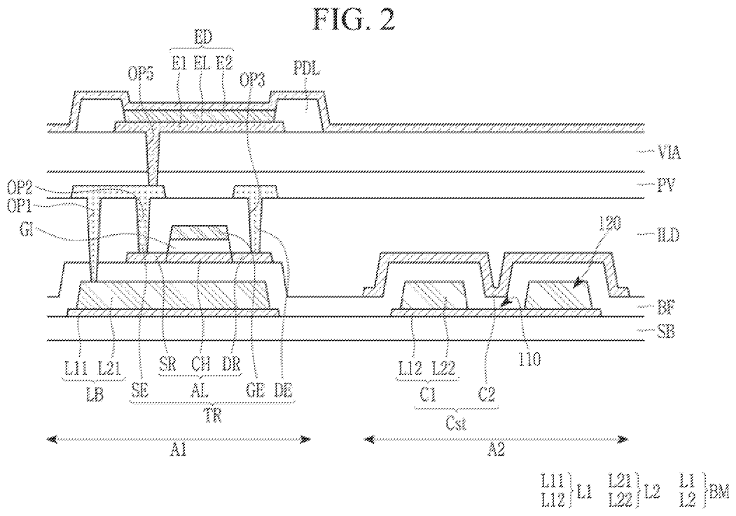

FIG. 2 illustrates a schematic cross-sectional view of a display device according to an embodiment. The schematic cross-section illustrated in FIG. 2 may correspond to approximately one pixel area. A transistor area A1 of FIG. 2 is an area in which the driving transistor T1 is positioned on the substrate, and a capacitor area A2 is an area in which the storage capacitor Cst is positioned on the substrate. The display device according to an embodiment includes a substrate SB, a transistor TR positioned on the substrate SB, a storage capacitor Cst, and a light emitting diode ED connected to the transistor TR.

The substrate SB may be a rigid substrate, such as a glass substrate. The substrate SB may be a flexible substrate SB capable of bending, folding, rolling, or the like. For example, the substrate SB may include a polymer resin such as polyimide (PI), polyamide (PA), or polyethylene terephthalate (PET). The substrate SB may be a single layer or a multilayer. In the substrate SB, at least one base layer including a polymer resin sequentially formed and at least one inorganic layer may be alternately positioned.

A lower conductive layer BM including a light blocking layer LB and a first capacitor electrode C1 may be positioned on the substrate SB. The lower conductive layer BM may be a double layer including the first conductive layer L1 and the second conductive layer L2 positioned on the first conductive layer L1. The second conductive layer L2 may be thicker than the first conductive layer L1. For example, the second conductive layer L2 may be equal to or greater than about 5000 Å. In an embodiment, the second conductive layer L2 may have a thickness in a range of about 5000 Å to about 8000 Å.

The first conductive layer L1 may include a titanium (Ti) layer. The second conductive layer L2 may include a copper (Cu) layer or an aluminum (Al) layer. For example, the lower conductive layer BM may be a Ti/Cu double layer formed to include a titanium (Ti) layer and a copper (Cu) layer, and may be a Ti/A1 double layer formed to include a titanium (Ti) layer and an aluminum (Al) layer. The lower conductive layer BM may further include an additional conductive layer (not illustrated) on the first conductive layer L1 and the second conductive layer L2. For example, the lower conductive layer BM may be a triple layer of Ti/Cu/Ti formed to include a titanium (Ti) layer, a copper (Cu) layer, and a titanium (Ti) layer, and may be a triple layer of Ti/Al/Ti formed to include a titanium (Ti) layer, an aluminum (Al) layer, and a titanium (Ti) layer. In an embodiment, the lower conductive layer BM may include a transparent conductive oxide (TCO) such as an indium tin oxide (ITO) or an indium zinc oxide (IZO). For example, the lower conductive layer BM may be formed as a triple layer of Ti/Cu/TCO, TCO/Cu/TCO, Ti/Al/TCO, and TCO/Al/TCO.

In the transistor area A1, the light blocking layer LB may be a light blocking layer that protects the semiconductor AL of the transistor TR from external light. The light blocking layer LB may be disposed to cover the semiconductor AL positioned thereon under the semiconductor AL. The light blocking layer LB may be formed to include a first conductive layer L11 and a second conductive layer L21 on the first conductive layer L11.

In the capacitor area A2, the first capacitor electrode C1 may include a first conductive layer L12 and a second conductive layer L22 disposed on the first conductive layer L12. The first capacitor electrode C1 may be formed as a double layer including the first conductive layer L12 and the second conductive layer L22. The second conductive layer L22 may be disposed on the first conductive layer L12. The second conductive layer L22 may be thicker than the first conductive layer L12.

The first capacitor electrode C1 may include a concave portion 110 from which the second conductive layer L22 is removed on the first conductive layer L12 in the vertical direction, and a convex portion 120 in which the second conductive layer L22 may be left on the first conductive layer L12. The concave portion 110 may be thinner than the convex portion 120. The convex portion 120 may be higher than the concave portion 110 based on an upper surface of the substrate SB. Accordingly, the first capacitor electrode C1 may include protrusions and depressions as a whole.

A buffer layer BF may be disposed on the substrate SB and the lower conductive layer BM to flatten the surface of the substrate SB and block penetration of impurities in case that the semiconductor layer is formed. The buffer layer BF may include an inorganic insulating material such as a silicon nitride (SiNₓ), a silicon oxide (SiOₓ), and a silicon oxynitride (SiOₓN_{y}), and may be a single layer or multiple layers. The buffer layer BF may include amorphous silicon (a-Si). In the capacitor area A2, the buffer layer BF may include protrusions and depressions corresponding to the concave portion 110 and the convex portion 120 of the first capacitor electrode C1.

A semiconductor layer including the semiconductor AL and the second capacitor electrode C2 may be disposed on the buffer layer BF. Components included in the semiconductor layer may be formed of a same material in a same process. For example, the semiconductor layer may be deposited and patterned to form the semiconductor AL and the second capacitor electrode C2. The semiconductor layer may include any one of an oxide semiconductor, amorphous silicon, and polycrystalline silicon. The oxide semiconductor may include at least one of zinc (Zn), indium (In), gallium (Ga), or tin (Sn). For example, the semiconductor layer may include low-temperature polycrystalline silicon (LTPS) or indium-gallium-zinc oxide (IGZO).

In the transistor area A1, the semiconductor AL may include a first region SR, a second region DR, and a channel region CH therebetween.

In the capacitor area A2, the second capacitor electrode C2 may include protrusions and depressions corresponding to shapes of the concave portion 110 and the convex portion 120 of the first capacitor electrode C1. The first capacitor electrode C1 and the second capacitor electrode C2 may form two electrodes of the storage capacitor Cst with the buffer layer BF provided therebetween. In the vertical direction, the first capacitor electrode C1 may have a concave portion 110 on the first conductive layer L12 from which the second conductive layer L22 is removed and a convex portion 120 on which the second conductive layer L22 is left. The second capacitor electrode C2 may include concavities and convexities corresponding to the concave portion 110 and the convex portion 120 of the first capacitor electrode C1. Accordingly, each electrode area of the storage capacitor Cst may be increased to correspond to the concave portion 110 and the convex portion 120 of the first capacitor electrode C1.

Accordingly, even when the area is limited in a plan view, the capacitance of the capacitor may be increased by increasing an electrode area of the capacitor. In case that the capacitance of the capacitor is increased, the gate voltage of the driving transistor T1 may be more stably maintained, and as a result, the display device may more stably emit light, thereby improving display quality.

A gate insulating layer GI may be disposed on the semiconductor AL in the transistor area A1. The gate insulating layer GI may include an inorganic insulating material such as a silicon nitride (SiNₓ), a silicon oxide (SiOₓ), and a silicon oxynitride (SiOₓN_{y}), and may be a single layer or multiple layers.

A third conductive layer (or gate conductive layer) including a gate electrode GE of the transistor TR may be disposed on the gate insulating layer GI. The gate electrode GE may overlap the channel region CH of the semiconductor AL. The third conductive layer may include a metal such as copper (Cu), molybdenum (Mo), aluminum (Al), silver (Ag), chromium (Cr), or tantalum (Ta), or a metal alloy thereof, and it may be formed as a single layer or a multilayer. Components included in the third conductive layer may be formed of a same material in a same process.

An interlayer insulating layer ILD may be disposed on the third conductive layer and the second capacitor electrode C2. The interlayer insulating layer ILD may include an inorganic insulating material such as a silicon nitride (SiNₓ), a silicon oxide (SiOₓ), and a silicon oxynitride (SiOₓN_{y}), and may be a single layer or multiple layers.

A fourth conductive layer (or source/drain conductive layer) including the first electrode SE and the second electrode DE of the transistor TR may be disposed on the interlayer insulating layer ILD. The first electrode SE of the transistor TR may be connected to the light blocking layer LB and may be connected to the first region SR of the semiconductor AL through openings OP1 and OP2 formed in the interlayer insulating layer ILD. The second electrode DE of the transistor TR may be connected to the second region DR of the semiconductor AL through opening OP3 formed in the interlayer insulating layer ILD. One of the first electrode SE and the second electrode DE may serve as a source electrode, and the other may serve as a drain electrode. Accordingly, the semiconductor AL, the gate electrode GE, the first electrode SE, and the second electrode DE constitute one transistor TR. The fourth conductive layer may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), and the like, and may be a single layer or multiple layers.

A passivation layer PV may be disposed on the fourth conductive layer. The passivation layer PV covers and protects the first electrode SE, the second electrode DE, and the interlayer insulating layer ILD of the transistor TR. The passivation layer PV may include an inorganic insulating material such as a silicon nitride (SiNₓ), a silicon oxide (SiOₓ), or a silicon oxynitride (SiOₓN_{y}), and may be a single layer or multiple layers.

A planarization layer VIA for planarizing the surface of the substrate SB may be disposed on the passivation layer PV. The planarization layer VIA may include an organic insulating material such as a general purpose polymer such as polymethyl methacrylate (PMMA), polystyrene (PS), a polymer derivative having a phenolic group, an acrylic polymer, an imide-based polymer (e.g., polyimide(PI)), and a siloxane-based polymer.

A first electrode E1 of the light emitting diode ED may be positioned on the planarization layer VIA. The first electrode E1 of the light emitting diode ED may be referred to as a pixel electrode. The first electrode E1 may include a transparent conductive material such as an indium tin oxide (ITO) or an indium zinc oxide (IZO). The first electrode E1 may include a metal such as lithium (Li), calcium (Ca), aluminum (Al), silver (Ag), magnesium (Mg), or gold (Au), or a metal alloy. The first electrode E1 of the light emitting diode ED may be connected to the first electrode SE of the transistor TR through opening OP5 of the passivation layer PV and the planarization layer VIA. Accordingly, the first electrode E1 may be electrically connected to the transistor TR to receive a driving current for controlling luminance of the light emitting diode.

A pixel defining layer PDL may be disposed on an edge portion of the first electrode E1 and on the planarization layer VIA. The pixel defining layer PDL may be referred to as a bank or a partition wall, and includes a pixel opening overlapping at least a portion of the first electrode E1. The pixel defining layer PDL may include an organic insulating material, e.g., a general purpose polymer such as poly(methyl methacrylate) (PMMA) or polystyrene (PS), a polymer derivative having a phenolic group, an acrylic polymer, an imide-based polymer, and a siloxane-based polymer. In another embodiment, the pixel defining layer PDL may include an inorganic insulating material such as a silicon nitride (SiNₓ), a silicon oxide (SiOₓ), and a silicon oxynitride (SiOₓN_{y}).

An emission layer EL of the light emitting diode LED may be disposed on the first electrode E1. In addition to the emission layer EL, a functional layer including at least one of a hole injection layer, a hole transport layer, an electron transport layer, and an electron injection layer may be disposed on the first electrode E1.

A second electrode E2 of the light emitting diode ED may be disposed on the emission layer EL. The second electrode E2 of the light emitting diode ED may be referred to as a common electrode. The second electrode E2 may be made of a low work function metal such as calcium (Ca), barium (Ba), magnesium (Mg), aluminum (Al), silver (Ag), or a metal alloy, as a thin layer to have light transmittance. The second electrode E2 may include a transparent conductive oxide (TCO) such as an indium tin oxide (ITO) or an indium zinc oxide (IZO).

The first electrode E1, the emission layer EL, and the second electrode E2 of each pixel may constitute a light emitting diode ED, such as an organic light emitting diode. The first electrode E1 of the light emitting diode ED may be an anode that may be a hole injection electrode, and the second electrode E2 may be a cathode that may be an electron injection electrode. In case that holes and electrons are injected from the first electrode E1 and the second electrode E2 into the emission layer (EL), excitons formed by combining the injected holes and electrons may be emitted when they fall from an excited state to a ground state. However, the anode and the cathode may be reversed depending on a driving method of the display device.

An encapsulation layer (not illustrated) and a cover window (not illustrated) for protecting the light emitting diode ED may be positioned on the light emitting diode ED.

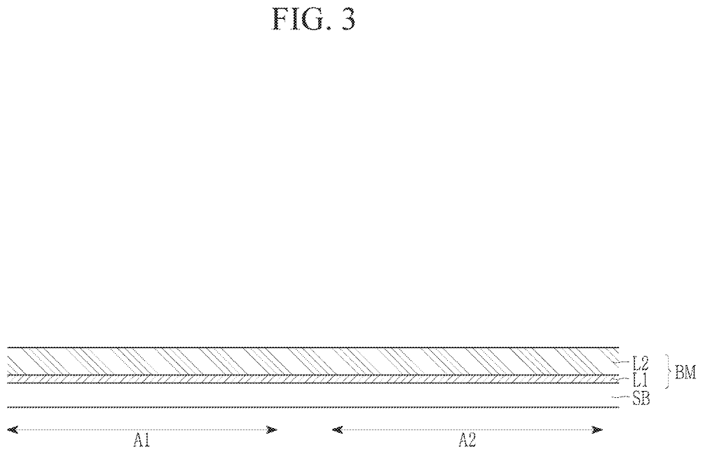

A manufacturing process of a display device according to an embodiment will be described with reference to FIG. 3 to FIG. 15.

Referring to FIG. 3, first, the lower conductive layer BM may be formed on the substrate SB. The lower conductive layer BM may include the first conductive layer L1 and the second conductive layer L2 positioned on the first conductive layer L1. The second conductive layer L2 may be thicker than the first conductive layer L1. For example, a titanium (Ti) layer may be formed as the first conductive layer L1, and a copper layer (Cu) may be formed as the second conductive layer L2. The copper (Cu) layer may be thicker than the titanium (Ti) layer, and for example, may have a thickness of equal to or greater than about 5000 Å. According to an embodiment, aluminum (Al) may be formed as the second conductive layer L2, and for example, may have a thickness of equal to or greater than about 6000 Å.

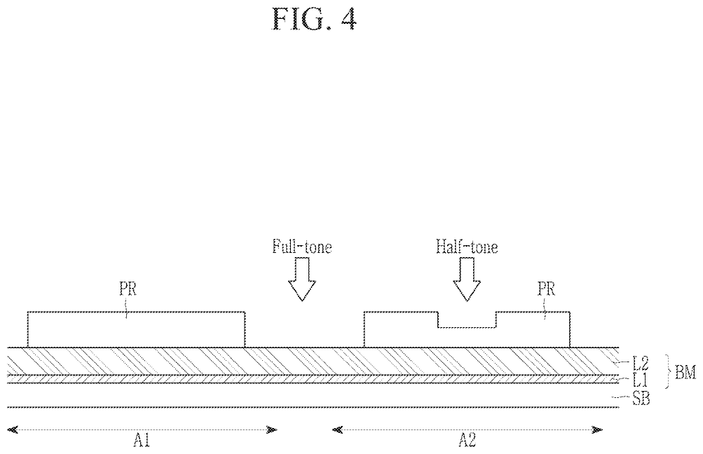

Subsequently, after a photoresist PR, which may be a photosensitive material, is applied on the substrate SB, the photoresist may be patterned as illustrated in FIG. 4. The patterning may indicate forming a given pattern by removing a portion of the layer through a photolithography process or the like. The capacitor area A2 may be patterned using a half-tone mask. The half-tone mask includes a blocking region that completely blocks light, a transmissive region that completely transmits light, and a semi-transmissive region that transmits a partial amount of light, and thus a thickness of the photoresist PR may be differently patterned by using the half-tone mask.

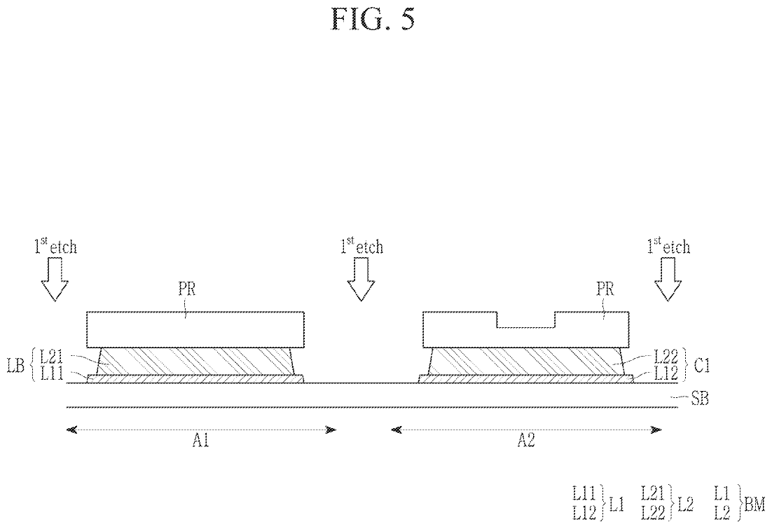

As illustrated in FIG. 5, a first etching process is performed. The first etching process may be a wet etching process, and the lower conductive layer BM that does not overlap the photoresist pattern may be etched to pattern the light blocking layer LB and the first capacitor electrode C1. In the first etching process, both the first conductive layer L1 and the second conductive layer L2 may be etched to form a first conductive layer L11 and a second conductive layer L21 in the transistor area A1, and a first conductive layer L12 and a second conductive layer L22 may be formed in the capacitor area A2.

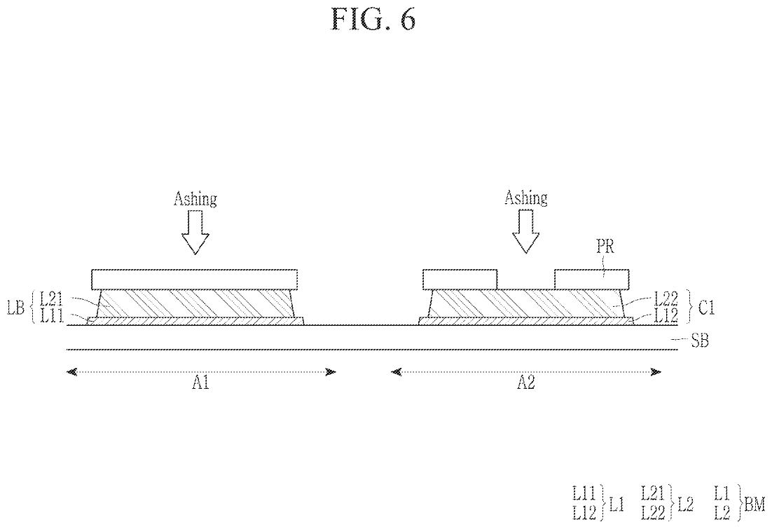

Subsequently, as illustrated in FIG. 6, an ashing process may be performed on a pattern of the photoresist PR. Accordingly, the pattern of the photoresist PR of a half-exposed area may be removed from the capacitor area A2 to expose the second conductive layer L22 of the half-exposed area to the outside.

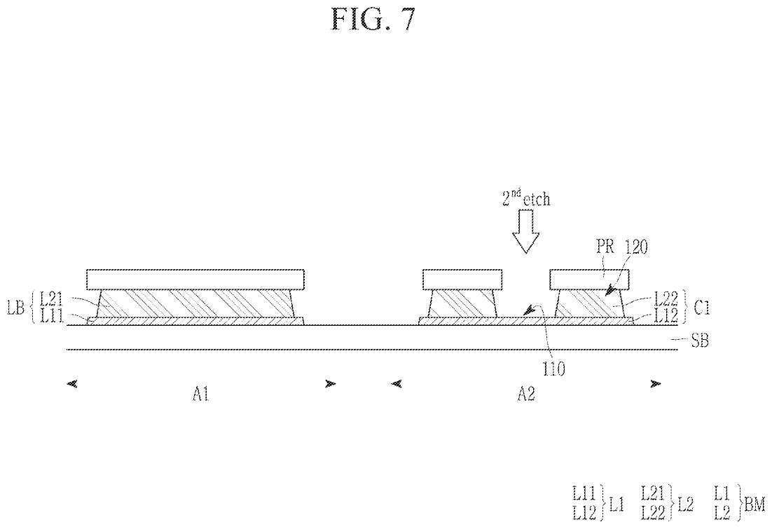

Subsequently, as illustrated in FIG. 7, a second etching process of etching the second conductive layer L22 in a portion where the pattern of the photoresist PR is not formed in the capacitor area A2 may be performed. In the second etching process, only the second conductive layer L22 may be etched by using an etchant having a selectivity to the first conductive layer L12. For example, the second conductive layer L22 may be an etch target, and the first conductive layer L12 may be an etch stopper of the second conductive layer L22. Accordingly, the second conductive layer L22 may be over-etched beyond an etching end point, so that no residual layer may be left, thereby forming a uniform pattern over the entire substrate SB.

The first capacitor electrode C1 may include protrusions and depressions depending on a shape of a pattern of the second conductive layer L22 formed on the first conductive layer L12. In an embodiment, the first capacitor electrode C1 may include a concave portion 110 from which the second conductive layer L22 may be removed on the first conductive layer L12 in the vertical direction, and a convex portion 120 in which the second conductive layer L22 may be left on the first conductive layer L12. The concave portion 110 may be thinner than the convex portion 120. The convex portion 120 may be higher than the concave portion 110 based on an upper surface of the substrate SB. Accordingly, the first capacitor electrode C1 may include protrusions and depressions as a whole.

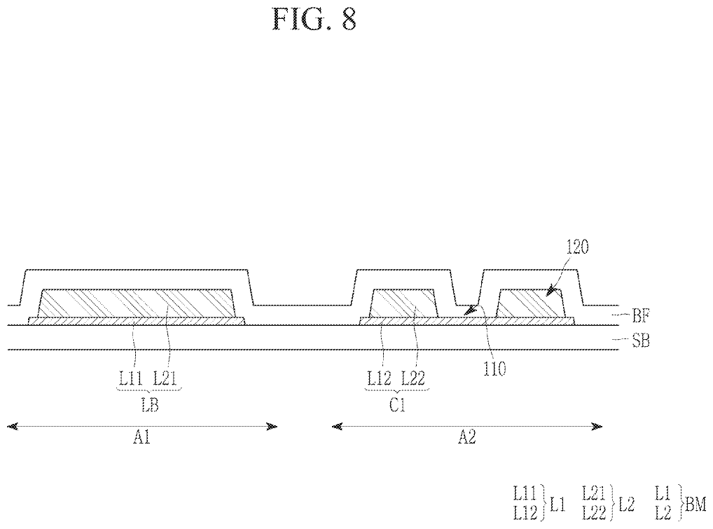

Subsequently as illustrated in FIG. 8, the photoresist PR may be removed, and a buffer layer BF is formed on the light blocking layer LB and the first capacitor electrode C1 by using an inorganic insulating material such as a silicon nitride (SiNₓ), a silicon oxide (SiOₓ), or a silicon oxynitride (SiOₓN_{y}). The buffer layer BF may be formed entirely on the substrate SB. In the capacitor area A2, the buffer layer BF may include protrusions and depressions corresponding to shapes of the concave portion 110 and the convex portion 120 of the first capacitor electrode C1.

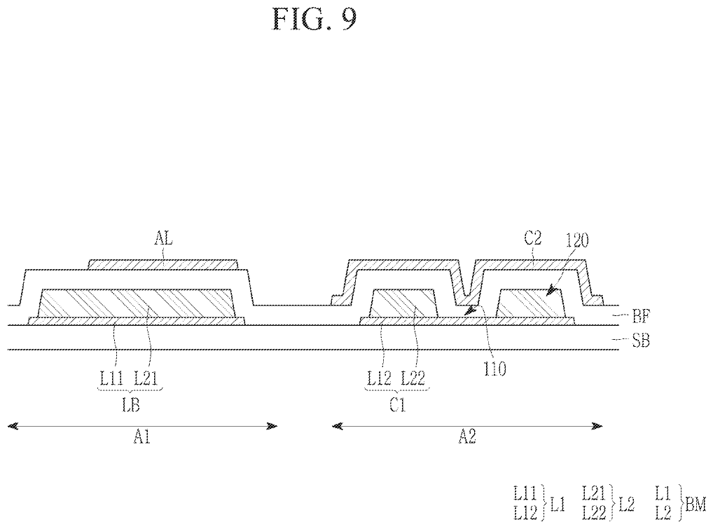

Subsequently as illustrated in FIG. 9, a semiconductor layer may be formed on the buffer layer BF by using a material such as an oxide semiconductor, amorphous silicon, and polycrystalline silicon, and the semiconductor AL and the second capacitor electrode C2 are patterned. The semiconductor AL and the second capacitor electrode C2 included in the semiconductor layer may be formed of a same material in a same process. In the capacitor area A2, the second capacitor electrode C2 may include protrusions and depressions corresponding to shapes of the concave portion 110 and the convex portion 120 of the first capacitor electrode C1.

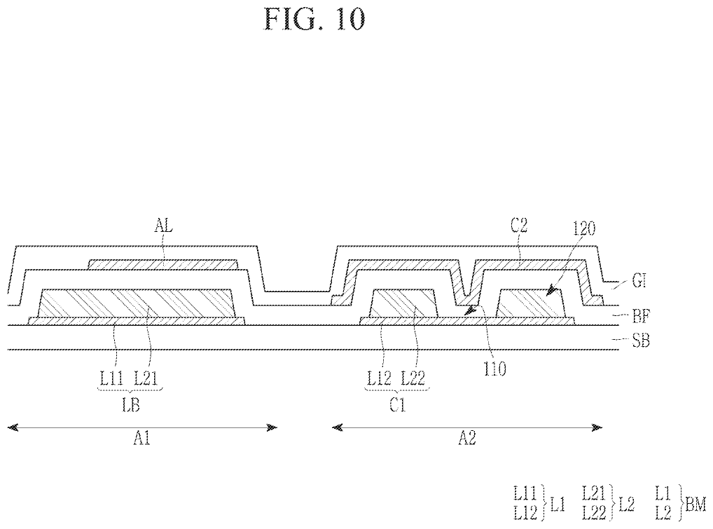

Subsequently as illustrated in FIG. 10, the gate insulating layer GI may be formed on the semiconductor layer and the buffer layer BF by using an inorganic insulating material such as a silicon nitride (SiNₓ), a silicon oxide (SiOₓ), or a silicon oxynitride (SiOₓN_{y}).

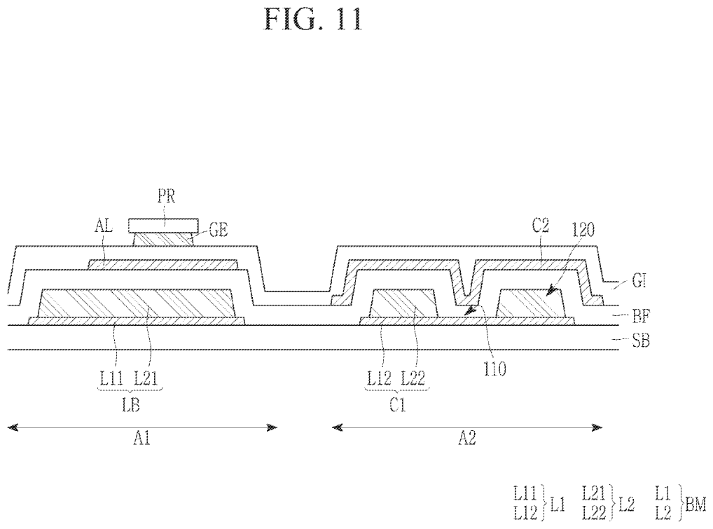

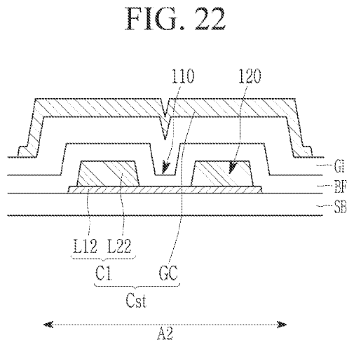

Subsequently as illustrated in FIG. 11, a third conductive layer containing a metal or metal alloy such as copper (Cu), molybdenum (Mo), aluminum (Al), silver (Ag), chromium (Cr), tantalum (Ta), or titanium (Ti) may be deposited on the gate insulating layer GI, and the gate electrode GE is patterned. Components included in the third conductive layer may be formed of a same material in a same process. In an embodiment, the third conductive layer may be patterned in the capacitor area A2 to form a second capacitor electrode. Hereinafter, it will be described with reference to FIG. 22.

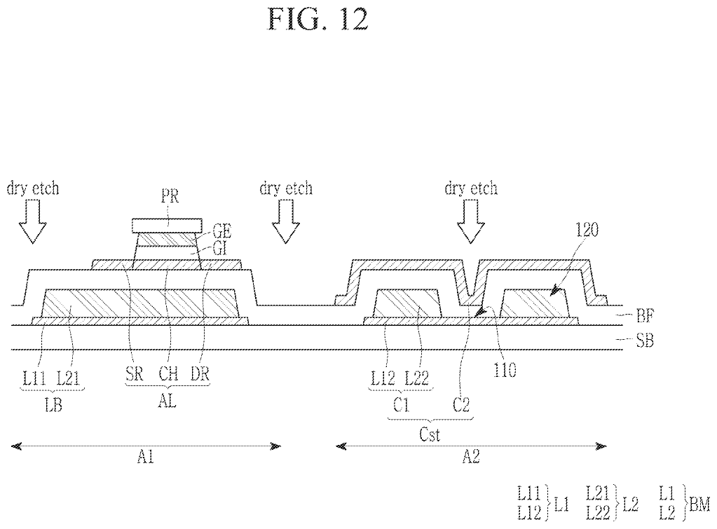

Subsequently as illustrated in FIG. 12, an etching process of the gate insulating layer GI may be performed. The etching process of the gate insulating layer GI may be a dry etching process, and may etch the gate insulating layer GI that does not overlap the pattern of the photoresist PR to expose the semiconductor layer to the outside. The dry etching process may include a doping process or a plasma treatment.

A portion of the semiconductor AL that is covered by the gate electrode GE in the transistor area A1 may be the channel region CH without being doped or plasma-treated. The first region SR and the second region DR of the semiconductor AL not covered by the gate electrode GE may be doped or subjected to plasma treatment to have a same characteristic as a conductor.

Since dry etching of the gate insulating layer GI is performed in the capacitor region A2, the second capacitor electrode C2 may be doped or plasma-treated to serve as an electrode having the same characteristic as a conductor. Accordingly, the first capacitor electrode C1 and the second capacitor electrode C2 may form two electrodes of the storage capacitor Cst with the buffer layer BF provided therebetween. The first capacitor electrode C1 includes a concave portion 110 and a convex portion 120 and the second capacitor electrode C2 includes protrusions and depressions corresponding to shapes of the concave portion 110 and the convex portion 120 of the first capacitor electrode C1, and thus an electrode area of the storage capacitor Cst may be increased to correspond to a concave-convex structure of the first capacitor electrode C1. Accordingly, even when an area is limited in a plan view, the electrode area of the storage capacitor Cst may be increased to secure sufficient capacitor capacitance and to perform stable external compensation.

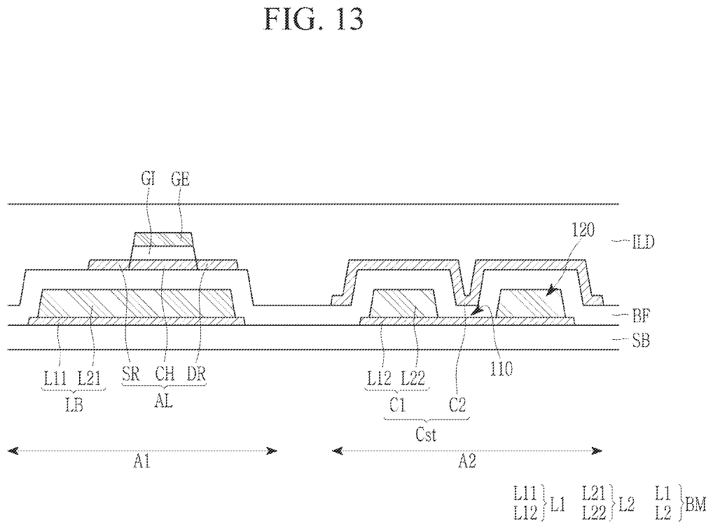

Subsequently as illustrated in FIG. 13, the photoresist PR is removed, an interlayer insulating layer ILD may be formed by using an inorganic insulating material such as a silicon nitride (SiNₓ), a silicon oxide (SiOₓ), or a silicon oxynitride (SiOₓN_{y}).

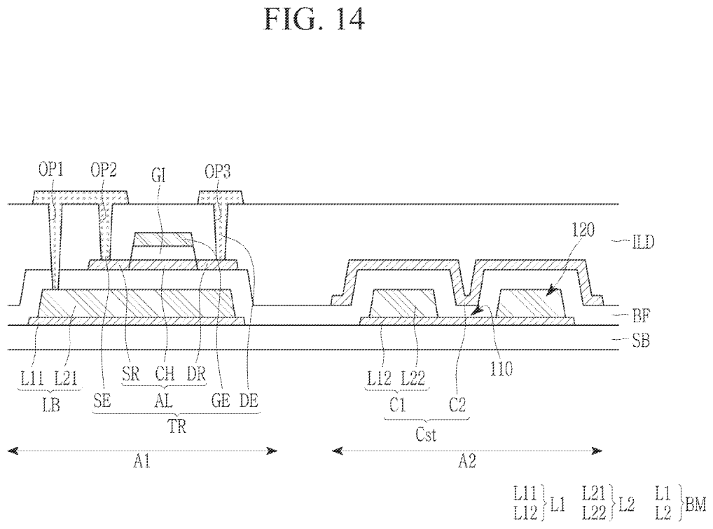

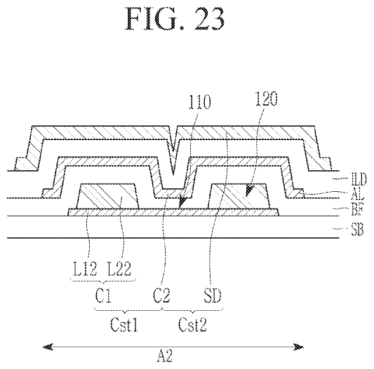

Subsequently as illustrated in FIG. 14, the openings OP1, OP2, and OP3 may be formed by patterning the interlayer insulating layer ILD and the buffer layer BF using a photolithography process. Thereafter, the first electrode SE and the second electrode DE of the transistor TR may be formed by depositing a fourth conductive layer including a metal such as aluminum (Al), copper (Cu), silver (Ag), gold (Au), platinum (Pt), palladium (Pd), nickel (Ni), molybdenum (Mo), tungsten (W), titanium (Ti), chromium (Cr), tantalum (Ta), etc., or a metal alloy thereof on the interlayer insulating layer ILD, and patterning it. Components included in the fourth conductive layer may be formed of a same material in a same process. In an embodiment, the fourth conductive layer may be patterned in the capacitor area A2 to form a second capacitor electrode. Hereinafter, it will be described with reference to FIG. 23.

The first electrode SE of the transistor TR may be connected to the light blocking layer LB through the opening OP1, and may be connected to the first region SR of the semiconductor AL through the opening OP2. The second electrode DE of the transistor TR may be connected to the second region DR of the semiconductor AL through the opening OP3.

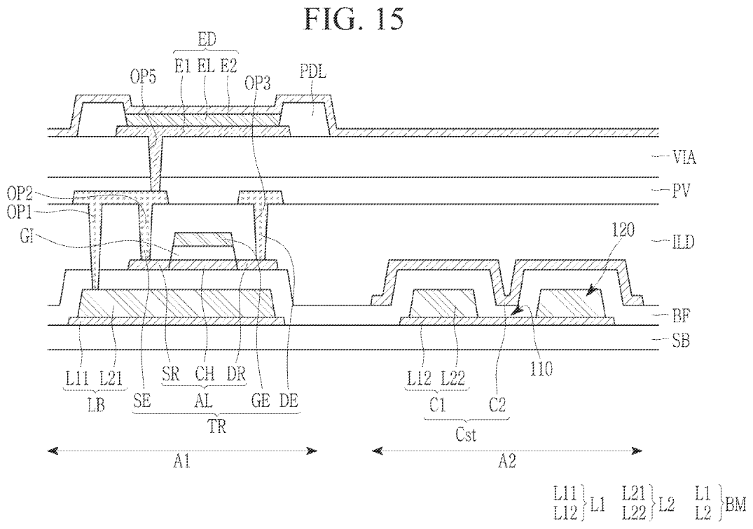

Subsequently as illustrated in FIG. 15, the passivation layer PV may be formed on the first electrode SE and the second electrode DE of the transistor TR by using an inorganic insulating material such as a silicon nitride (SiNₓ), a silicon oxide (SiOₓ), or a silicon oxynitride (SiOₓN_{y}). The planarization layer VIA including an organic insulating material such as a general purpose polymer such as polymethyl methacrylate (PMMA), polystyrene (PS), a polymer derivative having a phenolic group, an acrylic polymer, an imide-based polymer (e.g., polyimide(PI)), and a siloxane-based polymer may be formed on the passivation layer PV. The opening OP5 may be formed by patterning each of the passivation layer PV and the planarization layer VIA using a photolithography process. The opening OP5 may be formed by simultaneously patterning the passivation layer PV and the planarization layer VIA.

Subsequently, the first electrode E1 of the light emitting diode ED including a transparent conductive oxide or a metal material may be formed on the planarization layer VIA. The first electrode E1 may be connected to the first electrode SE of the transistor TR through opening OP5 of the passivation layer PV and the planarization layer VIA. The pixel defining layer PDL may be formed on an edge portion of the first electrode E1 of the light emitting diode ED and the planarization layer VIA. The pixel defining layer PDL may include an opening exposing the first electrode E1. The emission layer EL may be formed on the first electrode E1 in the opening, and the second electrode E2 of the light emitting diode ED may be formed on the pixel defining layer PDL and the emission layer EL.

Thereafter, the display device may be sealed from an external environment by forming an encapsulation layer (not illustrated) on the second electrode E2 or bonding an encapsulation substrate (not illustrated) to the substrate SB.

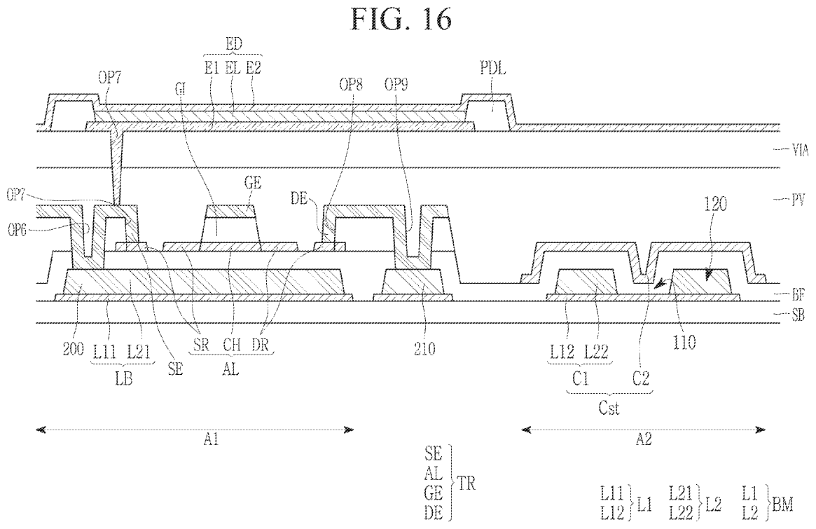

FIG. 16 illustrates a schematic cross-sectional view of a display device according to an embodiment.

Since the display device according to the embodiment illustrated in FIG. 16 is substantially the same as the display device according to the embodiment shown in FIG. 2, a description of the same parts will be omitted.

The schematic cross-section illustrated in FIG. 16 may correspond to approximately one pixel area. A transistor area A1 of FIG. 16 may be an area in which the driving transistor T1 is positioned on the substrate, and a capacitor area A2 may be an area in which the storage capacitor Cst is positioned on the substrate. The display device according to an embodiment may include a substrate SB, a transistor TR positioned on the substrate SB, a storage capacitor Cst, and a light emitting diode ED connected to the transistor TR.

A lower conductive layer BM including a light blocking layer LB and a first capacitor electrode C1 may be positioned on the substrate SB. In the transistor area A1, the light blocking layer LB may include a first conductive layer L11 and a second conductive layer L21 disposed on the first conductive layer L11 and the second conductive layer L21 may be thicker than the first conductive layer L11.

In the capacitor area A2, the first capacitor electrode C1 may include a first conductive layer L12 and a second conductive layer L22 disposed on the first conductive layer L12. The first capacitor electrode C1 may be formed as a double layer including the first conductive layer L12 and the second conductive layer L22. The second conductive layer L22 may be disposed on the first conductive layer L12. The second conductive layer L22 may be thicker than the first conductive layer L12. The first capacitor electrode C1 may include a concave portion 110 from which the second conductive layer L22 is removed on the first conductive layer L12 in the vertical direction, and a convex portion 120 in which the second conductive layer L22 is left on the first conductive layer L12. The concave portion 110 may be thinner than the convex portion 120. The convex portion 120 may be higher than the concave portion 110 based on an upper surface of the substrate SB.

In an embodiment, the lower conductive layer BM may be patterned to further include a first wire 200 and a second wire 210. For example, the first wire 200 may include a data line DTL connected to the first electrode SE of the transistor TR, and the second wire 210 may include a first power line ELVDD connected to the second electrode DE of the transistor TR.

The buffer layer BF may be disposed on the lower conductive layer BM, and a semiconductor layer may be patterned on the buffer layer BF to form the semiconductor AL and the second capacitor electrode C2.

In the transistor area A1, the gate insulating layer GI may be disposed on the semiconductor AL, and the first electrode SE, the gate electrode GE, and the second electrode DE of the transistor TR may be positioned on the gate insulating layer GI. The gate electrode GE may overlap the channel region CH of the semiconductor AL. The first electrode SE of the transistor TR may be connected to the first wire 200 of the lower conductive layer BM through the opening OP6, and may be connected to the first region SR of the semiconductor AL through the opening OP7. The second electrode DE of the transistor TR may be connected to the second wire 210 of the lower conductive layer BM through the opening OP9, and may be connected to the second region DR of the semiconductor AL through the opening OP8.

In the capacitor area A2, the second capacitor electrode C2 may include protrusions and depressions corresponding to the concave portion 110 and the convex portion 120 of the first capacitor electrode C1. The first capacitor electrode C1 and the second capacitor electrode C2 may form two electrodes of the storage capacitor Cst with the buffer layer BF provided therebetween. Each electrode area of the storage capacitor Cst may be increased to correspond to the concave portion 110 and the convex portion 120 of the first capacitor electrode C1.

Subsequently, the passivation layer PV and the planarization layer VIA may be sequentially disposed, and the first electrode E1 of the light emitting diode ED is positioned thereon. The pixel defining layer PDL defining a pixel opening may be disposed on an edge of the first electrode E1 and on the planarization layer VIA. The emission layer EL may be disposed on the first electrode E1 of the pixel opening, and the second electrode E2 of the light emitting diode ED may be positioned on the emission layer EL.

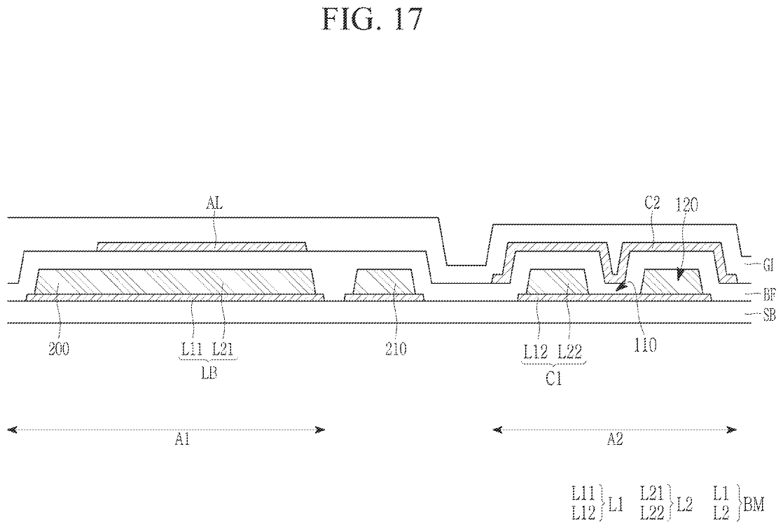

A manufacturing process of a display device according to an embodiment will be described with reference to FIG. 17 to FIG. 22.

Referring to FIG. 17, the lower conductive layer BM including the first conductive layer L1 and the second conductive layer L2 may be formed on the substrate SB, and the first wire 200, the light blocking layer LB, the second wire 210, and the first capacitor electrode C1 may be patterned by using a photolithography process. Thereafter, the buffer layer BF may be formed on the first wire 200, the light blocking layer LB, the second wire 210, and the first capacitor electrode C1 by using an inorganic insulating material. The semiconductor layer may be formed on the buffer layer BF, and the semiconductor AL and the second capacitor electrode C2 are patterned. In the capacitor area A2, the second capacitor electrode C2 may include protrusions and depressions corresponding to shapes of the concave portion 110 and the convex portion 120 of the first capacitor electrode C1. The gate insulating layer GI may be formed on the semiconductor layer.

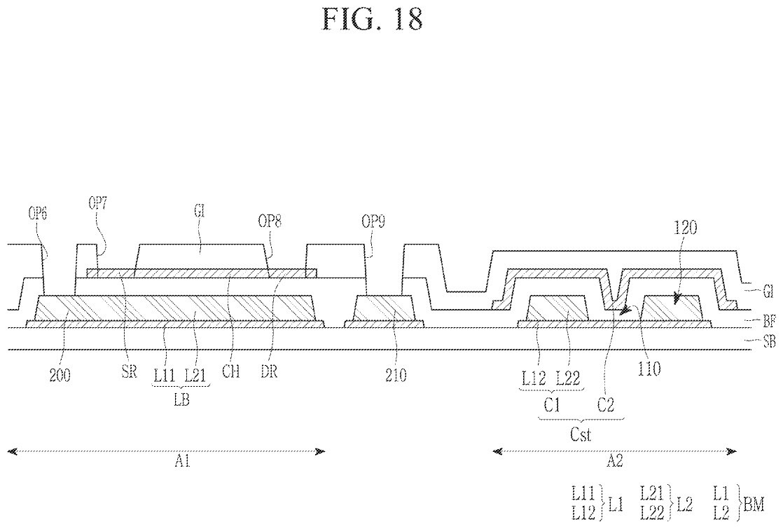

Referring to FIG. 18, openings OP6, OP7, OP8, and OP9 may be formed by patterning the gate insulating layer GI and the buffer layer BF using a photolithography process. The openings OP6, OP7, OP8, and OP9 may include an opening OP6 overlapping the first wire 200 of the lower conductive layer BM, an opening OP7 overlapping the first region SR of the semiconductor AL, an opening OP8 overlapping the second region DR of the semiconductor AL, and an opening OP9 overlapping the second wire 210 of the lower conductive layer BM. The semiconductor regions SR and DR exposed to the outside through the openings OP7 and OP8 may be doped or subjected to plasma treatment to have a same characteristic as the conductor.

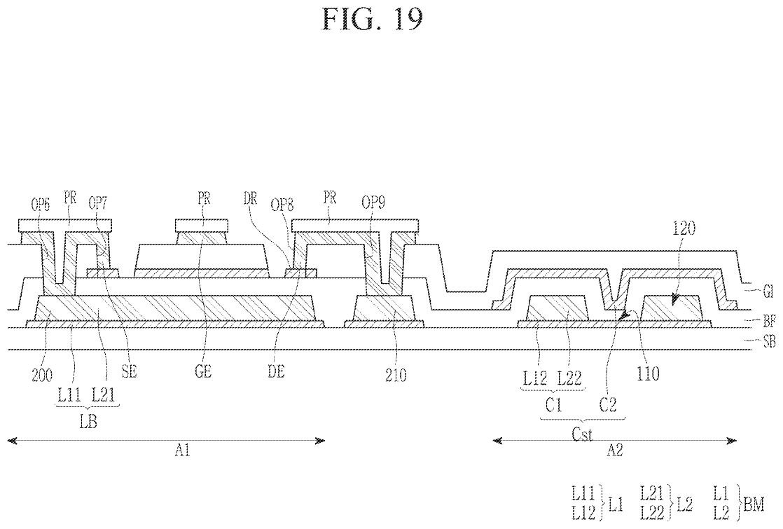

Subsequently, referring to FIG. 19, a third conductive layer may be deposited on the gate insulating layer GI, and the first electrode SE, the gate electrode GE, and the second electrode DE of the transistor TR may be patterned by using a photolithography process. The first electrode SE of the transistor TR may be connected to the first wire 200 of the lower conductive layer BM through the opening OP6, and may be connected to the first region SR of the semiconductor AL through the opening OP7. The second electrode DE of the transistor TR may be connected to the second wire 210 of the lower conductive layer BM through the opening OP9, and may be connected to the second region DR of the semiconductor AL through the opening OP8. Portions of the semiconductor AL may be etched and removed in the openings OP7 and OP8 exposed to the outside during an etching process.

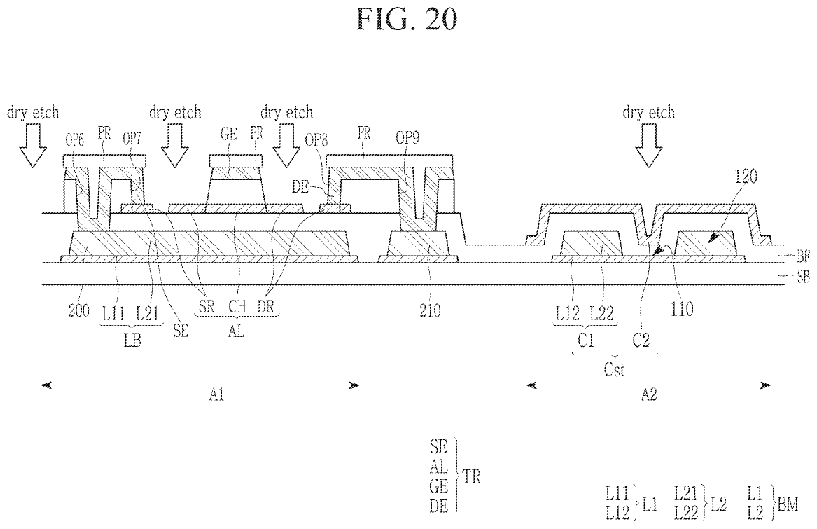

Subsequently, referring to FIG. 20, a dry etching process for removing the gate insulating layer GI may be performed. Portions of the semiconductor layer exposed to the outside in the transistor area A1 and the capacitor area A2 may be doped or subjected to plasma treatment to have a same characteristic as the conductor. Accordingly, the semiconductor AL, the gate electrode GE, the first electrode SE, and the second electrode DE in the transistor area A1 may constitute one transistor TR. In the capacitor area A2, the first capacitor electrode C1 and the second capacitor electrode C2 may form two electrodes of the storage capacitor Cst with the buffer layer BF provided therebetween. Each electrode area of the storage capacitor Cst may be increased to correspond to the concave portion 110 and the convex portion 120 of the first capacitor electrode C1. Accordingly, even when the area is limited in a plan view, the capacitance of the capacitor may be increased by increasing the electrode area of the storage capacitor Cst.

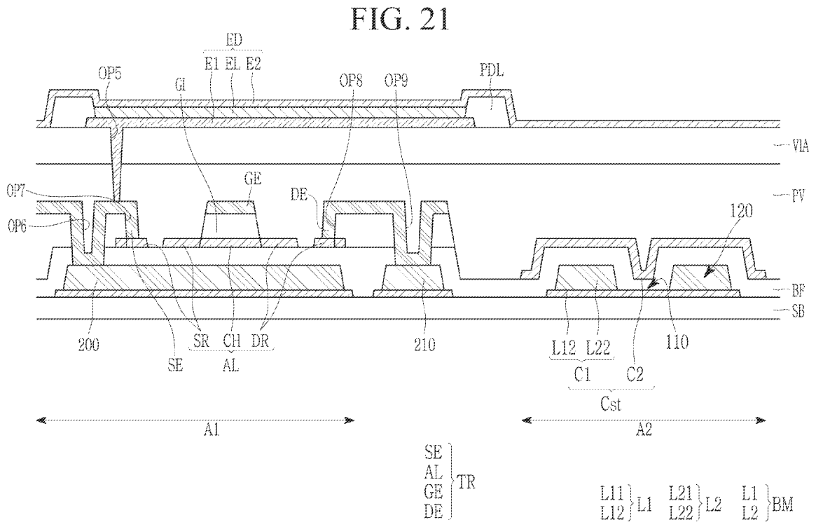

Subsequently, the photoresist PR may be removed, and as illustrated in FIG. 21, the passivation layer PV and the planarization layer VIA may be formed and patterned to form the opening OP5. Thereafter, the first electrode E1 may be formed on the planarization layer VIA, and the first electrode E1 may be connected to the first electrode SE of the transistor TR through openings of the passivation layer PV and the planarization layer VIA. The pixel defining layer PDL may be formed on an edge of the first electrode E1 and the planarization layer VIA. The pixel defining layer PDL includes an opening exposing the first electrode E1. The emission layer EL may be formed on the first electrode E1 in the pixel opening, and the second electrode E2 may be formed on the pixel defining layer PDL and the emission layer EL.

FIG. 22 and FIG. 23 illustrate a capacitor area A2 according to an embodiment. The capacitor area A2 of FIG. 22 and FIG. 23 may be an area in which the storage capacitor Cst is positioned. In FIG. 22 and FIG. 23, the capacitor area A2 will be described because the display device and the transistor area A1 according to the previous embodiments may be the same. The display device according to an embodiment includes a substrate SB, a transistor TR positioned on the substrate SB, a storage capacitor Cst, and a light emitting diode ED connected to the transistor TR.

Referring to FIG. 22, in an embodiment, a first capacitor electrode C1 including a first conductive layer L12 and a second conductive layer L22 disposed on the first conductive layer L12 may be disposed on the substrate SB. The second conductive layer L22 may be thicker than the first conductive layer L12. The first capacitor electrode C1 may include a second conductive layer L22 that is patterned on the first conductive layer L12. The first capacitor electrode C1 may include a concave portion 110 from which the second conductive layer L22 is removed on the first conductive layer L12 in the vertical direction, and may include a convex portion 120 in which the second conductive layer L22 is left on the first conductive layer L12. The concave portion 110 may be thinner than the convex portion 120. The convex portion 120 may be higher than the concave portion 110 based on an upper surface of the substrate SB. Accordingly, the first capacitor electrode C1 may include protrusions and depressions as a whole.

The buffer layer BF may be disposed on the first capacitor electrode C1, and the gate insulating layer GI and a third conductive layer GC may be sequentially disposed on the buffer layer BF. The gate insulating layer GI may be the same layer as the gate insulating layer GI formed in the transistor area A1 described above. The third conductive layer GC may be formed in the transistor area A1 described above in the same photolithography process as that of the gate electrode GE. Accordingly, the gate electrode GE of the transistor TR may be on a same layer as the third conductive layer GC of the storage capacitor Cst.

The buffer layer BF, the gate insulating layer GI, and the third conductive layer GC may each include protrusions and depressions corresponding to shapes of the concave portion 110 and the convex portion 120 of the first capacitor electrode C1. The first capacitor electrode C1 and the third conductive layer GC may form two electrodes of the storage capacitor Cst with the buffer layer BF and the gate insulating layer GI provided therebetween. Each electrode area of the storage capacitor Cst may be widened to correspond to protrusions and depressions in the vertical direction of the first capacitor electrode C1. Accordingly, even when an area is limited in a plan view, the electrode area of the storage capacitor Cst may be increased to secure sufficient capacitor capacitance and to perform stable external compensation.

Referring to FIG. 23, in an embodiment, a first capacitor electrode C1 including a first conductive layer L12 and a second conductive layer L22 disposed on the first conductive layer L12 may be disposed on the substrate SB. The second conductive layer L22 may be thicker than the first conductive layer L12. The first capacitor electrode C1 may include a second conductive layer L22 that is patterned on the first conductive layer L12. The first capacitor electrode C1 may include a concave portion 110 from which the second conductive layer L22 is removed on the first conductive layer L12 in the vertical direction, and may include a convex portion 120 in which the second conductive layer L22 is left on the first conductive layer L12. The concave portion 110 may be thinner than the convex portion 120. The convex portion 120 may be higher than the concave portion 110 based on an upper surface of the substrate SB. Accordingly, the first capacitor electrode C1 may include protrusions and depressions as a whole.

The buffer layer BF may be disposed on the first capacitor electrode C1, and the second capacitor electrode C2 may be disposed on the buffer layer BF. The interlayer insulating layer ILD and the fourth conductive layer SD may be sequentially disposed on the second capacitor electrode C2. The second capacitor electrode C2 may be formed in the same photolithography process as that of the semiconductor AL of the transistor area A1 described above. The fourth conductive layer SD may be formed in the same photolithography process as that of the first electrode SE and the second electrode DE formed in the transistor area A1 described above. Accordingly, the second capacitor electrode C2 may be on a same layer as the semiconductor AL, and the fourth conductive layer SD may be on a same layer as the first electrode SE and the second electrode DE of the transistor TR.

The buffer layer BF, the second capacitor electrode C2, the interlayer insulating layer ILD, and the fourth conductive layer SD may each include protrusions and depressions corresponding to shapes of the concave portion 110 and the convex portion 120 of the first capacitor electrode C1. The first capacitor electrode C1 and the second capacitor electrode C2 may form two electrodes of the first storage capacitor Cst1 with the buffer layer BF provided therebetween. The second capacitor electrode C2 and the fourth conductive layer SD may form two electrodes of the second storage capacitor Cst2 with the interlayer insulating layer ILD provided therebetween. The electrode area of each of the first and second storage capacitors Cst1 and Cst2 may be widened to correspond to the protrusions and depressions in the vertical direction of the first capacitor electrode C1. Accordingly, even when an area is limited in a plan view, the electrode area of the storage capacitor may be increased to secure sufficient capacitor capacitance and to perform stable external compensation.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A display device comprising:
a first capacitor electrode disposed on a substrate to include a first conductive layer and a patterned second conductive layer disposed on the first conductive layer;
a buffer layer disposed on the first capacitor electrode;
a second capacitor electrode disposed on the buffer layer;
a driving transistor disposed on the substrate; and
a storage capacitor disposed on the substrate and electrically connected to the driving transistor, wherein
the first capacitor electrode includes a concave portion and a convex portion depending on a pattern of the second conductive layer,
the buffer layer and the second capacitor electrode each include protrusions and depressions corresponding to the concave portion and the convex portion of the first capacitor electrode, and
the first capacitor electrode and the second capacitor electrode form two electrodes of the storage capacitor.

2. The display device of claim 1, wherein the driving transistor includes:
a semiconductor disposed on the buffer layer to include a channel region, a first region, and a second region;
a gate electrode that overlaps the channel region in a plan view;
a first electrode electrically connected to the first region of the semiconductor; and
a second electrode electrically connected to the second region of the semiconductor.

3. The display device of claim 1, wherein the second conductive layer is thicker than the first conductive layer.

4. The display device of claim 3, wherein a thickness of the second conductive layer is equal to or greater than about 5000 Å.

5. The display device of claim 1, wherein the first conductive layer includes titanium or a transparent conductive oxide.

6. The display device of claim 5, wherein the second conductive layer includes copper or aluminum.

7. The display device of claim 2, wherein the second capacitor electrode and the semiconductor of the driving transistor are on a same layer.

8. The display device of claim 2, further comprising:
a light blocking layer disposed on the substrate and spaced apart from the first capacitor electrode, wherein
the light blocking layer is connected to the first electrode of the driving transistor.

9. The display device of claim 8, further comprising:
a wire disposed on the substrate and spaced apart from the light blocking layer and the first capacitor electrode, wherein
the wire is electrically connected to the second electrode of the driving transistor.

10. The display device of claim 9, wherein the first capacitor electrode, the light blocking layer, and the wire are on a same layer.

11. A display device comprising:
a first capacitor electrode disposed on a substrate to include a first conductive layer and a patterned second conductive layer disposed on the first conductive layer;
a buffer layer disposed on the first capacitor electrode;
a third conductive layer disposed on the buffer layer,
a driving transistor disposed on the substrate, and
a storage capacitor disposed on the substrate and electrically connected to the driving transistor, wherein
the first capacitor electrode includes a concave portion and a convex portion depending on a pattern of the second conductive layer,
the buffer layer and the third conductive layer each include protrusions and depressions corresponding to the concave portion and the convex portion of the first capacitor electrode, and
the first capacitor electrode and the third conductive layer form two electrodes of the storage capacitor.

12. The display device of claim 11, wherein the driving transistor includes:
a semiconductor disposed on the buffer layer to include a channel region, a first region, and a second region;
a gate electrode that overlaps the channel region in a plan view;
a first electrode electrically connected to the first region of the semiconductor; and
a second electrode electrically connected to the second region of the semiconductor.

13. The display device of claim 11, wherein the second conductive layer is thicker than the first conductive layer.

14. The display device of claim 11, further comprising:
a gate insulating layer disposed on the buffer layer, wherein
the gate insulating layer includes protrusions and depressions corresponding to the concave portion and the convex portion of the first capacitor electrode.

15. The display device of claim 12, wherein the third conductive layer of the storage capacitor and that of the gate electrode of the driving transistor are on a same layer.

16. A display device comprising:
a first capacitor electrode disposed on a substrate to include a first conductive layer and a patterned second conductive layer disposed on the first conductive layer;
a buffer layer disposed on the first capacitor electrode;
a second capacitor electrode disposed on the buffer layer;
an interlayer insulating layer disposed on the second capacitor electrode;
a fourth conductive layer disposed on the interlayer insulating layer;
a driving transistor disposed on the substrate; and
a first storage capacitor and a second storage capacitor disposed on the substrate and electrically connected to the driving transistor, wherein
the first capacitor electrode includes a concave portion and a convex portion depending on a pattern of the second conductive layer,
the buffer layer, the second capacitor electrode, the interlayer insulating layer, and the fourth conductive layer each include protrusions and depressions corresponding to the concave portion and the convex portion of the first capacitor electrode,
the first capacitor electrode and the second capacitor electrode form two electrodes of the first storage capacitor, and
the second capacitor electrode and the fourth conductive layer form two electrodes of the second storage capacitor.

17. The display device of claim 16, wherein the driving transistor includes:
a semiconductor disposed on the buffer layer to include a channel region, a first region, and a second region;
a gate electrode that overlaps the channel region in a plan view;
a first electrode electrically connected to the first region of the semiconductor; and
a second electrode electrically connected to the second region of the semiconductor.

18. The display device of claim 17, wherein the second capacitor electrode and the semiconductor of the driving transistor are on a same layer.

19. The display device of claim 17, wherein the fourth conductive layer of the second storage capacitor and the first electrode of the driving transistor are on a same layer.

20. The display device of claim 16, wherein a thickness of the second conductive layer is thicker than a thickness of the first conductive layer.
